(19) United States
(12) Patent Application Publication
(10) Pub. No.: US 2025/0255040 A1
(43) Pub. Date: Aug. 7, 2025

(54) LIGHT EMITTING ELEMENT AND DISPLAY DEVICE INCLUDING THE SAME

(71) Applicant: Samsung Display Co., LTD., Yongin-si (KR)

(72) Inventors: Dae Hong MIN, Yongin-si (KR); Jin Wan KIM, Yongin-si (KR); Su Jeong KIM, Yongin-si (KR)

(73) Assignee: Samsung Display Co., LTD., Yongin-si (KR)

(21) Appl. No.: 18/907,968

(22) Filed: Oct. 7, 2024

(30) Foreign Application Priority Data
Feb. 6, 2024 (KR) 10-2024-0018159

(51) Int. Cl. H01L 33/12; H01L 25/075; H01L 33/02; H01L 33/06; H01L 33/32

(52) U.S. Cl. CPC H10H 20/815; H01L 25/0753; H10H 20/812; H10H 20/8215; H10H 20/825

(57) ABSTRACT

A light emitting element includes a first semiconductor layer doped with a first conductivity type, a stress relief layer disposed on the first semiconductor layer, the stress relief layer including an indium-containing layer containing a nitride-based semiconductor material containing indium, and doped with the first conductivity type, a light emitting layer disposed on the stress relief layer, the light emitting layer including a quantum well layer containing a nitride-based semiconductor material containing indium in a composition greater than or equal to an indium composition of the indium-containing layer, and a second semiconductor layer disposed on the light emitting layer and doped with a second conductivity type, the indium composition of the indium-containing layer is in a range of about 30% to about 100% of an indium composition of the quantum well layer.

### CROSS-REFERENCE TO RELATED APPLICATION(S)

This application claims priority to and benefits of Korean Patent Application No. 10-2024-0018159 under 35 U.S.C. § 119 filed on Feb. 6, 2024, in the Korean Intellectual Property Office, the entire contents of which are incorporated herein by reference.

### BACKGROUND

### 1. Technical Field

The disclosure relates to a light emitting element and a display device including the same.

### 2. Description of the Related Art

A light emitting element is widely used as a light source in various electronic devices, including a display device. For example, the light emitting element is used as a light source in various electronic devices, including portable electronic devices and televisions, as well as virtual reality (VR) devices, augmented reality (AR) devices, and the like.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a light emitting element with improved color purity and a display device including the same.

However, aspects of the disclosure are not restricted to the ones set forth herein. The above and other aspects of the disclosure will become more apparent to one of ordinary skill in the art to which the disclosure pertains by referencing the detailed description of the disclosure given below.

According to an aspect of the disclosure, there is provided a light emitting element that may include a first semiconductor layer doped with a first conductivity type; a stress relief layer disposed on the first semiconductor layer, the stress relief layer including an indium-containing layer containing a nitride-based semiconductor material containing indium, and doped with the first conductivity type; a light emitting layer disposed on the stress relief layer, the light emitting including a quantum well layer containing a nitride-based semiconductor material containing indium in a composition greater than or equal to an indium composition of the indium-containing layer, and a second semiconductor layer disposed on the light emitting layer and doped with a second conductivity type. The indium composition of the indium-containing layer may be in a range of about 30% to about 100% of an indium composition of the quantum well layer.

In an embodiment, a doping concentration of the indium-containing layer may be about 1016/cm³ or more.

In an embodiment, a doping concentration of the indium-containing layer may be lower than a doping concentration of the first semiconductor layer.

In an embodiment, a thickness of the indium-containing layer may be about 2 nm or more.

In an embodiment, the light emitting element may further include a superlattice layer disposed between the first semiconductor layer and the stress relief layer. The superlattice layer may be formed as multiple layers in which a first layer containing a nitride-based semiconductor material containing indium and a second layer containing a nitride-based semiconductor material that does not contain indium may be alternately disposed.

In an embodiment, an indium composition of the first layer of the superlattice layer may be less than about 30% of the indium composition of the quantum well layer.

In an embodiment, the superlattice layer may be doped at a doping concentration lower than or equal to a doping concentration of the first semiconductor layer.

In an embodiment, the light emitting element may further include a spacer layer disposed between the superlattice layer and the stress relief layer, the spacer layer containing a nitride-based semiconductor material that does not contain indium, and a thickness of the spacer layer may be about 20 nm or more.

In an embodiment, the quantum well layer may contain InGaN, and the indium-containing layer may contain InGaN or InAlGaN.

In an embodiment, the indium-containing layer may directly contact the light emitting layer.

In an embodiment, the stress relief layer may be a single layer formed of the indium-containing layer, and an indium composition of the stress relief layer may gradually change from a lower portion adjacent to the first semiconductor layer to an upper portion adjacent to the light emitting layer.

In an embodiment, the stress relief layer may be formed as multiple layers in which a plurality of indium-containing layers including the indium-containing layer and a plurality of intermediate layers containing a nitride-based semiconductor material that does not contain indium may be alternately disposed.

In an embodiment, an indium composition of the plurality of indium-containing layers may gradually change from the indium-containing layer at a lower portion adjacent to the first semiconductor layer to the indium-containing layer at an upper portion adjacent to the light emitting layer.

In an embodiment, a doping concentration of the stress relief layer may gradually change from a lower portion adjacent to the first semiconductor layer to an upper portion adjacent to the light emitting layer.

In an embodiment, the doping concentration of the stress relief layer may gradually decrease from a lower portion adjacent to the first semiconductor layer to an upper portion adjacent to the light emitting layer.

In an embodiment, an indium fluctuation in the light emitting layer may be at least about 10% higher than an indium fluctuation in the stress relief layer.

In an embodiment, the indium composition of the quantum well layer may be about 25% or more, and an emission wavelength of the light emitting layer may be in a range of about 500 nm to about 750 nm.

According to an aspect of the disclosure, there is provided a display device that may include a pixel including a first pixel electrode, a second pixel electrode, and a light emitting element electrically connected between the first pixel electrode and the second pixel electrode. The light emitting element may include a first semiconductor layer doped with a first conductivity type, a stress relief layer disposed on the first semiconductor layer, the stress relief layer including an indium-containing layer containing a nitride-based semiconductor material containing indium, and doped with the first conductivity type, a light emitting layer disposed on the stress relief layer, the light emitting layer including a quantum well layer containing a nitride-based semiconductor material containing indium, and a second semiconductor layer disposed on the light emitting layer and doped with a second conductivity type, and an indium composition of the indium-containing layer may be in a range of about 30% to about 100% of an indium composition of the quantum well layer.

In an embodiment, a doping concentration of the indium-containing layer may be about 1016/cm³ or more.

In an embodiment, the light emitting element may further include a superlattice layer disposed between the first semiconductor layer and the stress relief layer, and the superlattice layer may contain a nitride-based semiconductor material containing indium in a composition less than about 30% of the indium composition of the quantum well layer.

The light emitting element according to embodiments may include a stress relief layer disposed between a first semiconductor layer doped with a first conductivity type and a light emitting layer. The stress relief layer may include an indium-containing layer including a nitride-based semiconductor material including indium, and may be doped. The indium composition of the indium-containing layer may be in a range of about 30% to about 100% of the indium composition of the quantum well layer constituting the light emitting layer.

According to embodiments, a high-quality light emitting element with improved color purity and a display device including the same may be provided. For example, although a long-wavelength light emitting element in which the indium composition of the quantum well layer is about 25% or more is manufactured, in-plane strain may be alleviated, and indium may be smoothly injected into a quantum well layer due to the lattice matching effect by the stress relief layer formed prior to the formation of the quantum well layer. By doping the stress relief layer, light of a wavelength corresponding to the indium composition of the stress relief layer may be prevented from being generated in the stress relief layer. Accordingly, a high-quality light emitting element with improved color purity and reduced defects while emitting long-wavelength light, such as green light or red light, and a display device including the same may be provided.

However, effects according to the embodiments of the disclosure are not limited to those described above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic cross-sectional view illustrating a light emitting element according to one embodiment;

FIG. 2 is a schematic cross-sectional view illustrating the light emitting element according to one embodiment;

FIG. 3 is a schematic cross-sectional view illustrating the light emitting element according to one embodiment;

FIG. 4 is a schematic cross-sectional view illustrating the light emitting element according to one embodiment;

FIG. 5 is a schematic cross-sectional view illustrating a light emitting layer according to one embodiment;

FIG. 6 is a schematic cross-sectional view illustrating a stress relief layer according to one embodiment;

FIG. 7 is a schematic cross-sectional view illustrating a superlattice layer according to one embodiment;

FIG. 8 is a schematic cross-sectional view illustrating the stress relief layer according to one embodiment;

FIG. 9 is a schematic cross-sectional view illustrating the stress relief layer according to one embodiment;

FIG. 10 is a schematic cross-sectional view illustrating the stress relief layer according to one embodiment;

FIG. 11 is a schematic perspective view illustrating a display device according to one embodiment;

FIG. 12 is a schematic plan view showing an example of area μl of FIG. 11;

FIG. 13 is a schematic cross-sectional view illustrating a display panel according to one embodiment;

FIG. 14 is a diagram illustrating a virtual reality device including a display device according to one embodiment;

FIG. 15 is a diagram illustrating a smart device including a display device according to one embodiment;

FIG. 16 illustrates an automobile dashboard and center fascia including display devices according to one embodiment; and

FIG. 17 is a diagram illustrating a transparent display device including a display device according to one embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Features of each of various embodiments of the disclosure may be partially or entirely combined with each other and may technically variously interwork with each other, and respective embodiments may be implemented independently of each other or may be implemented together in association with each other.

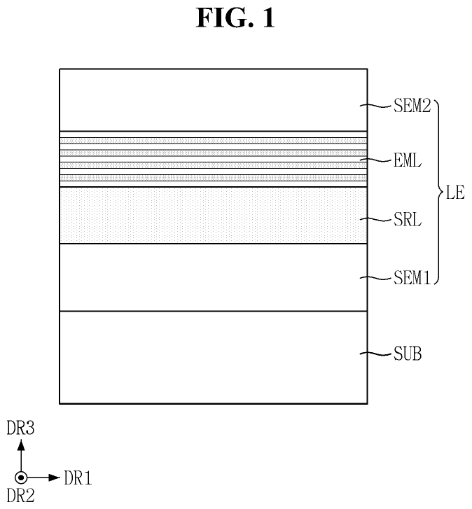

FIG. 1 is a schematic cross-sectional view illustrating a light emitting element LE according to one embodiment.

Referring to FIG. 1, the light emitting element LE may be disposed on a substrate SUB. For example, the light emitting element LE may be manufactured on the substrate SUB and separated from the substrate SUB.

FIG. 1 shows a first direction DR1, a second direction DR2, and a third direction DR3 that are perpendicular to each other. For example, the first direction DR1 and the second direction DR2 may be perpendicular to each other and define a plane parallel to the bottom surface (for example, lower surface or upper surface) of the light emitting element LE or the substrate SUB. The third direction DR3 may be perpendicular to the first direction DR1 and the second direction DR2. For example, the third direction DR3 may be a direction perpendicular to the main surface of the substrate SUB and may be a height direction or a thickness direction of the substrate SUB or the light emitting element LE.

The substrate SUB (also referred to as “growth substrate” or “manufacturing substrate”) may be a semiconductor substrate for forming the light emitting element LE. The substrate SUB may be a manufacturing substrate, a wafer, or the like suitable for epitaxial growth. For example, a first semiconductor layer SEM1 of the light emitting element LE, a stress relief layer SRL (for example, strain relief layer), a light emitting layer EML, and a second semiconductor layer SEM2 may be formed by epitaxial growth on the substrate SUB.

In one embodiment, the substrate SUB may be a semiconductor substrate including silicon (Si), sapphire, GaAs, SiC, GaN, ZnO, or other materials. In case that epitaxial growth for manufacturing the light emitting element LE may be performed smoothly, the type or material of the substrate SUB is not particularly limited.

In one embodiment, the substrate SUB may be used as a substrate for epitaxial growth for manufacturing the light emitting element LE and may be finally separated from the light emitting element LE. For example, after sequentially forming (for example, growing or re-growing) semiconductor layers to form the light emitting element LE on the substrate SUB, f light emitting elements LE having a size (for example, an area smaller than the area of the substrate SUB) smaller than the size of the substrate SUB may be formed by an etching process, dicing, or the like within the spirit and the scope of the disclosure. For example, after forming the light emitting elements LE on the substrate SUB at the same time, the light emitting elements LE may be separated from the substrate SUB.

The light emitting element LE may have various forms depending on embodiments. In one embodiment, the light emitting element LE may include a side surface that is substantially perpendicular to the substrate SUB. For example, the light emitting element LE may have a cross-sectional shape such as a rectangular shape or a square shape. However, the shape of the light emitting element LE is not limited thereto. For example, the light emitting element LE may include a side surface inclined at an angle in a selectable range with respect to the substrate SUB. For example, the light emitting element LE may have a cross-sectional shape such as a trapezoid or an inverted trapezoid. The light emitting element LE may have various planar shapes depending on embodiments. For example, the light emitting element LE may have a rectangular shape, a square shape, a hexagonal shape, a circular shape, an elliptical shape, or another planar shape when viewed on a plane defined by the first direction DR1 and the second direction DR2.

In one embodiment, the light emitting element LE may be an inorganic light emitting element made of an inorganic material. For example, the light emitting element LE may be an inorganic light emitting diode made of a nitride-based semiconductor material (for example, GaN, AlGaN, GaAIN, InGaN, InAlGaN, AlN, InN, or another nitride-based semiconductor material), or another inorganic material. The light emitting element LE may emit light of a given color. As an example, the light emitting element LE may emit red light, green light, blue light, or light of another color.

In one embodiment, the light emitting element LE may be a micro light emitting diode (micro LED) having a small size in the micrometer (μm) range. For example, the light emitting element LE may be a micro LED having a length (for example, horizontal length) in the first direction DR1, a length (for example, vertical length) in the second direction DR2, and a length (for example, thickness or height) in the third direction DR3, which are several to hundreds of micrometers, respectively. Each of the length of the light emitting element LE in the first direction DR1, the length in the second direction DR2, and the length in the third direction DR3 may be 100 μm or less, but is not limited thereto.

The light emitting element LE may include the first semiconductor layer SEM1, the stress relief layer SRL, the light emitting layer EML, and the second semiconductor layer SEM2 sequentially disposed on the substrate SUB. In one embodiment, the light emitting element LE may further include a passivation layer surrounding the outer peripheral surface (for example, side surface) of the first semiconductor layer SEM1, the stress relief layer SRL, the light emitting layer EML, and the second semiconductor layer SEM2.

The first semiconductor layer SEM1 may be disposed on the substrate SUB. The first semiconductor layer SEM1 may be a semiconductor layer doped with a first conductivity type. For example, the first semiconductor layer SEM1 may include a semiconductor material including a first conductivity type dopant.

In one embodiment, the first semiconductor layer SEM1 may include a nitride-based semiconductor material and a first conductivity type dopant doped into the nitride-based semiconductor material. For example, the first semiconductor layer SEM1 may be an n-type semiconductor layer (for example, n-GaN) doped with an n-type dopant such as Si, Ge, and Sn, but is not limited thereto.

The stress relief layer SRL may be disposed on the first semiconductor layer SEM1. For example, the stress relief layer SRL may be disposed between the first semiconductor layer SEM1 and the light emitting layer EML.

In embodiments, the stress relief layer SRL may include indium (In) and may be doped. In one embodiment, the stress relief layer SRL may be doped with a first conductivity type. For example, the stress relief layer SRL may include a nitride-based semiconductor material (for example, InGaN or InAlGaN) including indium, and a first conductivity type dopant doped into the nitride-based semiconductor material. In one embodiment, the stress relief layer SRL may include an n-type semiconductor layer (for example, n-InGaN or n-InAlGaN) including a nitride-based semiconductor material including indium and doped with an n-type dopant such as Si, Ge, and Sn, but is not limited thereto.

The stress relief layer SRL may be a single layer or multiple layers. As an example, the stress relief layer SRL may include at least one indium-containing layer including a nitride-based semiconductor material including indium. The stress relief layer SRL may include at least one intermediate layer that does not include (for example, substantially does not include) indium, or may not include an intermediate layer.

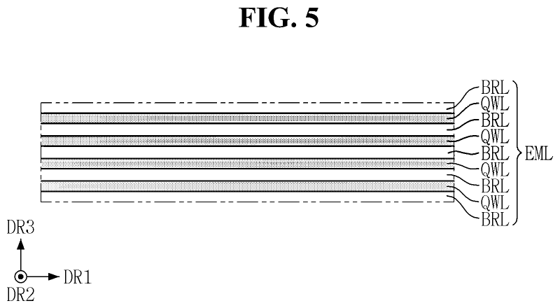

In one embodiment, the indium composition of the stress relief layer SRL (or the indium-containing layer included in the stress relief layer SRL) may be less than or equal to the indium composition of the quantum well layer (for example, a quantum well layer QWL of FIG. 5) included in the light emitting layer EML. In one embodiment, the indium composition of the stress relief layer SRL may be in a range of about 30% to about 100% of the indium composition of the quantum well layer.

In some embodiments, the indium composition of the stress relief layer SRL (or the indium-containing layer included in the stress relief layer SRL) may be as illustrated in Table 1 below. In Table 1, the wavelengths of the light emitting layer EML and the stress relief layer SRL are the wavelengths (for example, the emission wavelength) calculated according to the indium composition.

TABLE 1

| | | Embodiment | Embodiment | Embodiment | Embodiment |
|---|---|---|---|---|---|
| | Item | 1 | 2 | 3 | 4 |
| Light | Indium | 20 | 25 | 30 | 35 |
| emitting | composition | | | | |
| layer | [%] | | | | |
| (Quantum | Wavelength | 495 | 537 | 585 | 637 |
| well layer) | [nm] | | | | |
| Stress relief | Indium | ≥7 | ≥8.75 | ≥10.5 | ≥12.25 |
| layer | composition | | | | |
| (Indium- | [%] | | | | |
| containing | Wavelength | 403 | 413 | 425 | 435 |
| layer) | [nm] | | | | |

Referring to Table 1, in case that the indium composition (for example, the indium composition of the quantum well layer constituting the light emitting layer EML) of the light emitting layer EML is about 20% as in Embodiment 1, the indium composition (for example, the indium composition of the indium-containing layer constituting the stress relief layer SRL) of the stress relief layer SRL may be about 7% or more (for example, in a range of about 7% to about 20%). As in Embodiment 2, Embodiment 3, and Embodiment 4, in case that the indium compositions of the light emitting layer EML are about 25%, about 30%, and about 35%, respectively, the indium compositions of the stress relief layer SRL may be about 8.75% or more (for example, in a range of about 8.75% to about 25%), about 10.5% or more (for example, in a range of about 10.5% to about 30%), and about 12.25% or more (for example, in a range of about 12.25% to about 35%), respectively. The indium composition of the light emitting layer EML and the stress relief layer SRL is not limited to the embodiments disclosed in Table 1, and may change depending on the embodiments.

The stress relief layer SRL may alleviate lattice mismatch through lattice matching. For example, by disposing the stress relief layer SRL of a medium-sized lattice constant between the first semiconductor layer SEM1 and the light emitting layer EML, stress (for example, in-plain strain) due to the lattice constant differences between the first semiconductor layer SEM1 and the light emitting layer EML may be alleviated. In embodiments, by forming the stress relief layer SRL (or the indium-containing layer included in the stress relief layer SRL) to have an indium composition in a range of about 30% to about 100% of the indium composition of the quantum well layer, the lattice mismatch between the first semiconductor layer SEM1 and the light emitting layer EML may be more effectively alleviated and/or buffered. Accordingly, in the step of forming the light emitting layer EML on the stress relief layer SRL, indium may be smoothly injected into the light emitting layer EML according to the targeted indium composition, and the high-quality light emitting layer EML with reduced defects may be formed.

As the stress relief layer SRL is doped (for example, doped with a first conductivity type), light emission by the stress relief layer SRL may be prevented or reduced. In one embodiment, the doping concentration of the stress relief layer SRL (or the indium-containing layer included in the stress relief layer SRL) may be about 1016/cm³ or more. Accordingly, it is possible to effectively prevent the stress relief layer SRL from unintentionally emitting light. For example, although the stress relief layer SRL may include indium in a composition of about 30% or more of the indium composition of the quantum well layer, non-radiative recombination of carriers (for example, electrons or holes) may be caused by a first conductivity type dopant doped into the stress relief layer SRL, so that the generation of light of a different wavelength from that of the light emitting layer EML in the stress relief layer SRL may be prevented or reduced. The stress relief layer SRL may be appropriately doped, so that the stress relief layer SRL may be appropriately prevented from emitting light although a high current flows through the light emitting element LE. Accordingly, color mixing may be prevented and color purity of the light emitting element LE may be increased.

In one embodiment, the doping concentration of the stress relief layer SRL (or the indium-containing layer included in the stress relief layer SRL) may be less than or equal to the doping concentration of the first semiconductor layer SEM1. Accordingly, although the stress relief layer SRL is formed at a growth temperature lower than or equal to the growth temperature of the first semiconductor layer SEM1, the high-quality stress relief layer SRL with reduced defects may be formed, and defects that may occur at the interface between the stress relief layer SRL and the first semiconductor layer SEM1 may be reduced.

The stress relief layer SRL may be formed to have an appropriate thickness in consideration of at least one of the lattice matching effect, the manufacturing efficiency of the light emitting element LE, or the luminous efficiency of the light emitting element LE. For example, the stress relief layer SRL (or the indium-containing layer included in the stress relief layer SRL) may be formed to have a thickness of about 2 nm or more to obtain a desired lattice matching effect. Although the stress relief layer SRL is formed to have a thickness of about 2 nm or more, light emission of the stress relief layer SRL may be suppressed by doping.

In one embodiment, the thickness of the stress relief layer SRL may be formed to be less than or equal to the thickness of the light emitting layer EML. For example, the thickness of the stress relief layer SRL or each indium-containing layer constituting the stress relief layer SRL may be in a range of about 2 nm to about 5 nm, but is not limited thereto.

The light emitting layer EML may be disposed on the stress relief layer SRL. For example, the light emitting layer EML may be disposed between the stress relief layer SRL and the second semiconductor layer SEM2. The light emitting layer EML may emit light by recombination of electron-hole pairs generated in response to an electrical signal applied through the first semiconductor layer SEM1, the second semiconductor layer SEM2 and the like within the spirit and the scope of the disclosure.

The light emitting layer EML may include a nitride-based semiconductor material or another semiconductor material, and may have a single or multiple quantum well structure. For example, the light emitting layer EML may include at least one quantum well layer including a nitride-based semiconductor material including indium. In embodiments, the quantum well layer may include a nitride-based semiconductor material including indium in a composition greater than or equal to the indium composition of the stress relief layer SRL (or the indium-containing layer of the stress relief layer SRL). In one embodiment, the light emitting layer EML may have a multiple quantum well structure including quantum well layers including InGaN and barrier layers including GaN, AlGaN, or GaAIN, but is not limited thereto.

In one embodiment, the light emitting layer EML may emit light in a visible light wavelength band, for example, light in a wavelength band in a range of about 400 nm to about 900 nm. For example, the light emitting layer EML may emit blue light with a peak wavelength in the range of about 440 nm to about 480 nm, green light with a peak wavelength in the range of about 510 nm to about 550 nm, or red light with a peak wavelength in the range of about 610 nm to about 750 nm (for example, a range of about 610 nm to about 650 nm). The light emitting layer EML may emit light in a different color or a different wavelength band than the color or the wavelength band described above.

In one embodiment, the color of light emitted from the light emitting layer EML may be adjusted or changed by adjusting the composition (or content) of indium included in the light emitting layer EML. For example, by controlling the composition (or content) of indium included in the light emitting layer EML in a range of about 20% about 30%, the emission wavelength of the light emitting layer EML may be controlled such that the light emitting layer EML emits green light. By way of example, by controlling the composition (or content) of indium included in the light emitting layer EML in a range of about 30% about 40%, the emission wavelength of the light emitting layer EML may be controlled such that the light emitting layer EML emits red light.

In one embodiment, the indium composition (for example, the indium composition of the quantum well layer) of the light emitting layer EML may be about 25% or more, and the emission wavelength (for example, emission peak wavelength) of the light emitting layer EML may be in a range of about 500 nm to about 750 nm. For example, the light emitting layer EML may emit light (for example, green light or red light) of a long wavelength that is equal to or longer than the green wavelength band.

In one embodiment, the indium composition of the light emitting layer EML (or the quantum well layer included in the light emitting layer EML) may be higher the indium composition of the stress relief layer SRL (or the indium-containing layer included in the stress relief layer SRL). Accordingly, indium fluctuation in the light emitting layer EML may be higher than indium fluctuation in the stress relief layer SRL. For example, the indium fluctuation in the light emitting layer EML may be at least about 10% higher than the indium fluctuation in the stress relief layer SRL.

The second semiconductor layer SEM2 may be disposed on the light emitting layer EML. The second semiconductor layer SEM2 may be a semiconductor layer doped with a second conductivity type. For example, the second semiconductor layer SEM2 may include a semiconductor material including a second conductivity type dopant.

In one embodiment, the second semiconductor layer SEM2 may include a nitride-based semiconductor material and a second conductivity type dopant doped into the nitride-based semiconductor material. For example, the second semiconductor layer SEM2 may be a p-type semiconductor layer (for example, p-GaN) doped with a p-type dopant such as Mg, Zn, Ca, Se, and Ba, but is not limited thereto.

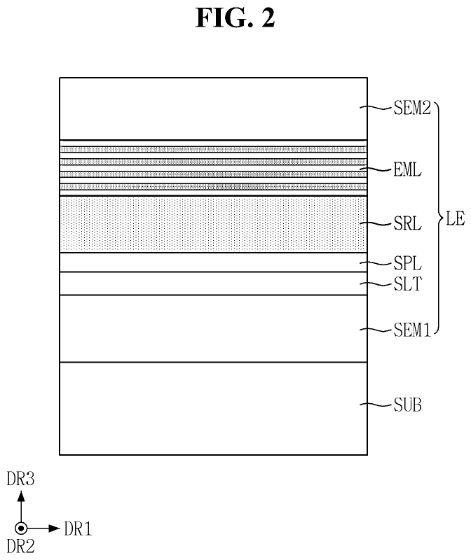

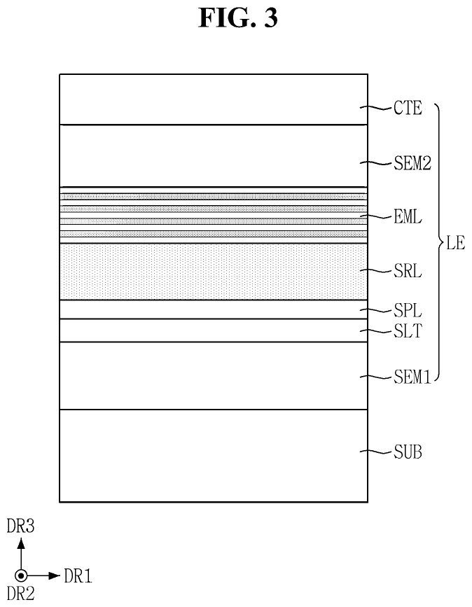

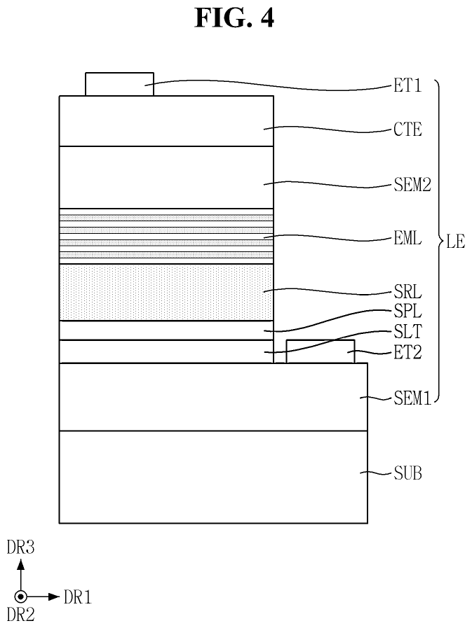

FIG. 2 is a schematic cross-sectional view illustrating the light emitting element LE according to one embodiment. FIG. 3 is a schematic cross-sectional view illustrating the light emitting element LE according to one embodiment. FIG. 4 is a schematic cross-sectional view illustrating the light emitting element LE according to one embodiment. For example, FIGS. 2 to 4 illustrate the respective light emitting elements LE according to different modified embodiments of the embodiment of FIG. 1.

Referring to FIGS. 1 and 2, the light emitting element LE may further include a superlattice layer SLT disposed between the first semiconductor layer SEM1 and the stress relief layer SRL. In one embodiment, the light emitting element LE may further include a spacer layer SPL disposed between the superlattice layer SLT and the stress relief layer SRL.

The superlattice layer SLT may include indium. As an example, the superlattice layer SLT may include a nitride-based semiconductor material including indium.

In embodiments, the indium composition of the superlattice layer SLT may be lower than the indium composition of the stress relief layer SRL. For example, the indium composition of the superlattice layer SLT may be less than about 30% of the indium composition of the quantum well layer included in the light emitting layer EML. For example, the indium composition of the superlattice layer SLT may be about 5% or less (for example, in a range of about 2% to about 5%), but is not limited thereto.

By disposing the superlattice layer SLT of an intermediate lattice size between the first semiconductor layer SEM1 and the stress relief layer SRL, a semiconductor layer (for example, the superlattice layer SLT, the stress relief layer SRL, and the light emitting layer EML) including indium may be grown smoothly on the first semiconductor layer SEM1, and defects that may occur in the surface (for example, the interface between the first semiconductor layer SEM1 and the superlattice layer SLT) of the first semiconductor layer SEM1 may be reduced. Accordingly, the high-quality and/or high-efficiency light emitting element LE may be manufactured.

In one embodiment, the superlattice layer SLT may be formed to be less than or equal to the thickness of the first semiconductor layer SEM1. The superlattice layer SLT may be formed as multiple layers including first layers including indium at a low concentration and second layers disposed between the first layers, and each first layer may be formed to have a limited thickness. As an example, each of the first layers of the superlattice layer SLT may be formed to have a thickness of about 2 nm or less. Accordingly, the superlattice layer SLT may be smoothly grown on the first semiconductor layer SEM1, and the conductivity of the superlattice layer SLT may be secured.

The superlattice layer SLT may be doped or undoped. In one embodiment, the superlattice layer SLT may be doped with a first conductivity type, and thus the conductivity of the superlattice layer SLT may be improved. In one embodiment, the doping concentration of the superlattice layer SLT may be less than or equal to the doping concentration of the first semiconductor layer SEM1. For example, the doping concentration of the first semiconductor layer SEM1 may be about 3*1018/cm³ or more, and the doping concentration of the superlattice layer SLT may be lower than about 3*1018/cm³. Accordingly, although the superlattice layer SLT is formed at a growth temperature lower than or equal to the growth temperature of the first semiconductor layer SEM1, the high-quality superlattice layer SLT with reduced defects may be formed, and defects that may occur at the interface between the superlattice layer SLT and the first semiconductor layer SEM1 may be reduced.

The spacer layer SPL may be disposed between the superlattice layer SLT and the stress relief layer SRL. In one embodiment, the spacer layer SPL may be formed of a semiconductor layer that does not include indium. For example, the spacer layer SPL may include a nitride-based semiconductor material (for example, GaN) that does not include indium. In one embodiment, the thickness of the spacer layer SPL may be about 20 nm or more. As the spacer layer SPL is disposed between the superlattice layer SLT and the stress relief layer SRL, the space corresponding to the spacer layer SPL may be secured between the superlattice layer SLT and the stress relief layer SRL, and the lattice may be adjusted smoothly and/or appropriately. The spacer layer SPL may be doped or undoped. The spacer layer SPL may be omitted.

Referring to FIGS. 1 to 3, the light emitting element LE may further include at least one contact electrode CTE. As an example, the light emitting element LE may further include the contact electrode CTE disposed on the second semiconductor layer SEM2. The contact electrode CTE may be provided to the light emitting element LE to protect the second semiconductor layer SEM2 and smoothly connect the second semiconductor layer SEM2 to at least one electrode, circuit element, or line, or the like within the spirit and the scope of the disclosure.

In one embodiment, in order to manufacture the light emitting element LE including the contact electrode CTE, the contact electrode CTE may be further formed after forming the second semiconductor layer SEM2 on the substrate SUB. In one embodiment, the contact electrode CTE may be entirely disposed on the second semiconductor layer SEM2. As an example, the contact electrode CTE may have a size corresponding to the second semiconductor layer SEM2 and may entirely cover the upper surface of the second semiconductor layer SEM2. Accordingly, the second semiconductor layer SEM2 may be appropriately or stably protected. However, the embodiments are not limited thereto. For example, the contact electrode CTE may be formed to cover only a portion of the second semiconductor layer SEM2 and expose another portion of the second semiconductor layer SEM2.

The contact electrode CTE may include metal, metal oxide, or other conductive materials. As an example, the contact electrode CTE may be made singly of or by mixing a metal such as chromium (Cr), titanium (Ti), aluminum (Al), gold (Au), nickel (Ni), or copper (Cu), an oxide or alloy thereof, or a transparent conductive material such as indium tin oxide (ITO), indium zinc oxide (IZO), indium tin zinc oxide (ITZO), zinc oxide (ZnO) or indium oxide (In₂O₃), but is not limited thereto.

In one embodiment, the light emitting element LE including the contact electrode CTE may include the superlattice layer SLT and the spacer layer SPL. However, the embodiments are not limited thereto. For example, the light emitting element LE including the contact electrode CTE may not include at least one of the superlattice layer SLT or the spacer layer SPL.

Referring to FIGS. 1 to 4, the light emitting element LE may further include a first electrode ET1 disposed on the contact electrode CTE (or the second semiconductor layer SEM2) and a second electrode ET2 disposed on the first semiconductor layer SEM1. In one embodiment, other upper semiconductor layers and/or the contact electrode CTE may be disposed on only a portion of the first semiconductor layer SEM1, and the other portion of the first semiconductor layer SEM1 may be exposed. The second electrode ET2 may be disposed on another portion of the first semiconductor layer SEM1. In one embodiment, the light emitting element LE may include only one of the first electrode ET1 and the second electrode ET2 and may not include the other electrode.

The first electrode ET1 may be a connection electrode (for example, a bonding electrode) to smoothly connect the contact electrode CTE (or the second semiconductor layer SEM2) to another circuit element, electrode, or line, or the like within the spirit and the scope of the disclosure. In one embodiment, the first electrode ET1 may have a smaller size than the contact electrode CTE, but is not limited thereto. In one embodiment, the first electrode ET1 may be connected to a first pixel electrode provided in each pixel of the display device. In one embodiment, the first electrode ET1 may have a size corresponding to the first pixel electrode, but is not limited thereto.

The second electrode ET2 may be a connection electrode (for example, a bonding electrode) to smoothly connect the first semiconductor layer SEM1 to another circuit element, electrode, line, or the like within the spirit and the scope of the disclosure. In one embodiment, the second electrode ET2 may have a smaller size than the exposed portion of the first semiconductor layer SEM1, but is not limited thereto. In one embodiment, the second electrode ET2 may be connected to a second pixel electrode provided in each pixel of the display device. In one embodiment, the second electrode ET2 may have a size corresponding to the second pixel electrode, but is not limited thereto.

The first electrode ET1 and the second electrode ET2 may include metal, metal oxide, or other conductive materials. For example, the first electrode ET1 and the second electrode ET2 may include any one of molybdenum (Mo), aluminum (Al), chromium (Cr), gold (Au), titanium (Ti), nickel (Ni), neodymium (Nd), and copper (Cu), but is not limited thereto.

In one embodiment, the light emitting element LE including at least one of the first electrode ET1 or the second electrode ET2 may include the superlattice layer SLT, the spacer layer SPL, and the contact electrode CTE. However, the embodiments are not limited thereto. For example, the light emitting element LE including at least one of the first electrode ET1 or the second electrode ET2 may not include at least one of the superlattice layer SLT, the spacer layer SPL, or the contact electrode CTE.

FIG. 5 is a schematic cross-sectional view illustrating the light emitting layer EML according to one embodiment. For example, FIG. 5 shows one embodiment of the light emitting layer EML shown in FIGS. 1 to 4.

Referring to FIGS. 1 to 5, the light emitting layer EML may have a multiple quantum well structure including the quantum well layers QWL and barrier layers BRL. For example, the light emitting layer EML may include the quantum well layers QWL and the barrier layers BRL alternately disposed on the stress relief layer SRL along the third direction DR3. In one embodiment, the respective barrier layers BRL may be disposed on the lowermost layer and the uppermost layer of the light emitting layer EML.

However, the embodiments are not limited thereto. For example, the light emitting layer EML may have a single quantum well structure including the single quantum well layer QWL.

The quantum well layer QWL may include a nitride-based semiconductor material including indium. As an example, the quantum well layer QWL may include InGaN, but is not limited thereto.

In embodiments, the indium composition of the quantum well layer QWL may be greater than or equal to the indium composition of the stress relief layer SRL. In one embodiment, the indium composition of the quantum well layer QWL may be about 25%, and the light generated from the quantum well layer QWL may be light of a long wavelength that is equal to or longer than the green wavelength band. The indium composition and emission wavelength of the quantum well layer QWL may be changed depending on embodiments.

The barrier layer BRL may not include indium. In one embodiment, the barrier layer BRL may include a nitride-based semiconductor material that does not include indium. As an example, the quantum well layer QWL may include GaN, but is not limited thereto.

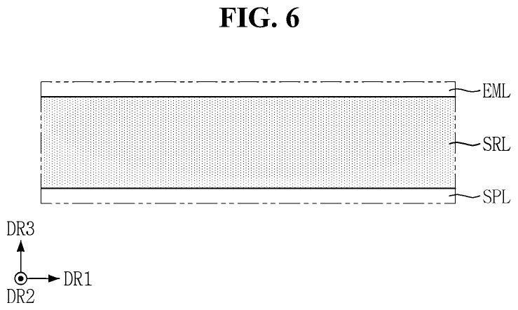

FIG. 6 is a schematic cross-sectional view illustrating the stress relief layer SRL according to one embodiment. For example, FIG. 6 illustrates one embodiment of the stress relief layer SRL illustrated in FIGS. 1 to 4.

Referring to FIGS. 1 to 6, the stress relief layer SRL may be formed as a single layer including indium. As an example, the stress relief layer SRL may be formed as a single indium-containing layer including indium with an overall uniform composition and/or concentration, and may be doped.

In one embodiment, the stress relief layer SRL may include InGaN or InAlGaN and may be doped with a first conductivity type. For example, the stress relief layer SRL may include a dopant of a first conductivity type. The doping concentration of the stress relief layer SRL may be uniform overall or may gradually change (for example, gradually decrease) along the third direction DR3.

In one embodiment, the indium composition of the stress relief layer SRL may be in a range of about 30% to about 100% of the indium composition of the quantum well layer QWL. In one embodiment, the doping concentration of the stress relief layer SRL may be about 1016/cm³ or more and may be lower than the doping concentration of the first semiconductor layer SEM1. In one embodiment, the thickness of the stress relief layer SRL may be about 2 nm or more and may be several micrometers (for example, about 3 μm) or less.

In one embodiment, the stress relief layer SRL may be directly in contact with the light emitting layer EML. As an example, the stress relief layer SRL may be in contact with the barrier layer BRL positioned at the lowermost portion of the light emitting layer EML and may be disposed very close to the quantum well layer QWL on the barrier layer BRL. Accordingly, the lattice matching effect by the stress relief layer SRL may be improved or secured, and indium may be more smoothly injected into the quantum well layer QWL in case that the light emitting layer EML is formed.

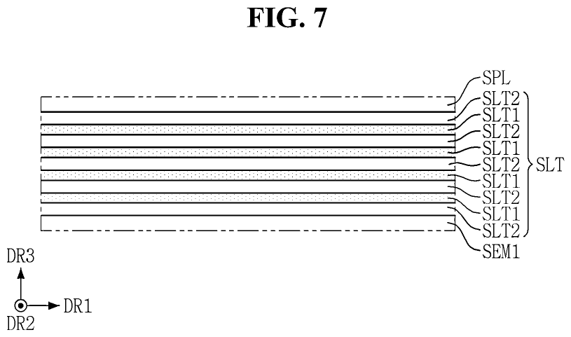

FIG. 7 is a schematic cross-sectional view illustrating the superlattice layer SLT according to one embodiment. For example, FIG. 7 illustrates one embodiment of the superlattice layer SLT illustrated in FIGS. 2 to 4.

Referring to FIGS. 2 to 7, the superlattice layer SLT may be formed as multiple layers including at least one pair of a first layer SLT1 and a second layer SLT2 sequentially or alternately disposed on the first semiconductor layer SEM1 along the third direction DR3. As an example, the superlattice layer SLT may include a multilayer structure including first layers SLT1 and second layers SLT2 alternately disposed on the first semiconductor layer SEM1 along the third direction DR3.

The first layer SLT1 may include indium. For example, the first layer SLT1 may include a nitride-based semiconductor material including indium. In one embodiment, the indium composition of the first layer SLT1 may be lower than the indium composition of the stress relief layer SRL. For example, the indium composition of the first layer SLT1 may be less than about 30% of the indium composition of the quantum well layer QWL. Accordingly, the superlattice layer SLT including the first layer SLT1 may be smoothly or appropriately formed on the first semiconductor layer SEM1.

In one embodiment, the first layer SLT1 may have a thickness limited to about 5 nm or less. For example, the thickness of the first layer SLT1 may be about 2 nm or less and may be smaller than the thickness of the stress relief layer SRL (or the indium-containing layer included in the stress relief layer SRL). Accordingly, the first layer SLT1 may be formed smoothly or appropriately, and the conductivity of the first layer SLT1 and the superlattice layer SLT including the first layer SLT1 may be improved or secured.

In one embodiment, the first layer SLT1 may be doped. As an example, the first layer SLT1 may be doped with a first conductivity type and thus may include a dopant of a first conductivity type. In one embodiment, the doping concentration of the first layer SLT1 may be less than or equal to the doping concentration of the first semiconductor layer SEM1. Accordingly, while the conductivity of the first layer SLT1 and the superlattice layer SLT including the same is improved, defects in the superlattice layer SLT and the light emitting element LE including the same may be reduced.

The second layer SLT2 may not include indium. For example, the second layer SLT2 may include a nitride-based semiconductor material that does not include indium.

In one embodiment, the second layer SLT2 may have a low thickness of about 5 nm or less. For example, the thickness of the second layer SLT2 may be about 2 nm or less and may be smaller than the thickness of the stress relief layer SRL (or the indium-containing layer included in the stress relief layer SRL). In one embodiment, the thickness of the first layer SLT1 and the second layer SLT2 may be substantially the same. Accordingly, the first layer SLT1 and the second layer SLT2 have a low thickness, so that the conductivity of the superlattice layer SLT may be improved or secured.

The second layer SLT2 may be doped or undoped. As an example, the second layer SLT2 may be doped with a first conductivity type or may be undoped. In one embodiment in which the second layer SLT2 is doped, the doping concentration of the second layer SLT2 may be less than or equal to the doping concentration of the first semiconductor layer SEM1. Accordingly, while the conductivity of the second layer SLT2 and the superlattice layer SLT including the same is improved, defects in the superlattice layer SLT and the light emitting element LE including the same may be reduced.

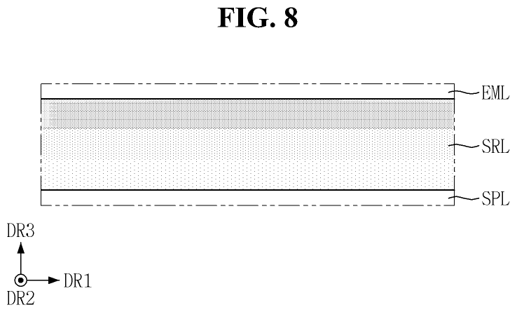

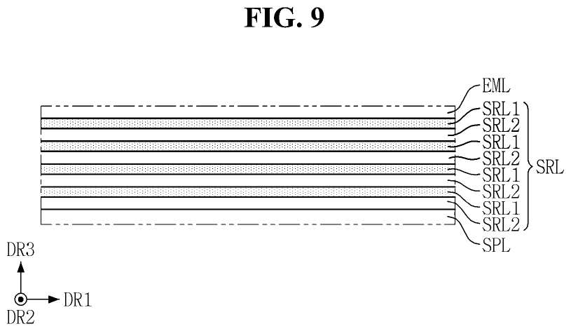

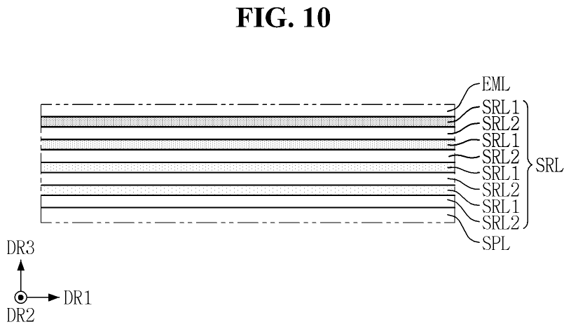

FIG. 8 is a schematic cross-sectional view illustrating the stress relief layer SRL according to one embodiment. FIG. 9 is a schematic cross-sectional view illustrating the stress relief layer SRL according to one embodiment. FIG. 10 is a schematic cross-sectional view illustrating the stress relief layer SRL according to one embodiment. For example, FIGS. 8 through 10 illustrate different embodiments of the stress relief layer SRL illustrated in FIGS. 1 through 4.

Referring to FIGS. 1 to 8, the stress relief layer SRL may be formed as a single layer including indium and may be doped. As an example, the stress relief layer SRL may be formed as a single indium-containing layer and may be doped with a first conductivity type.

In one embodiment, the indium composition of the stress relief layer SRL may gradually change from the lower portion adjacent to the first semiconductor layer SEM1 to the upper portion adjacent to the light emitting layer EML. For example, the indium composition of the stress relief layer SRL may gradually increase from the lower portion to the upper portion along the third direction DR3. For example, the stress relief layer SRL may be formed (for example, grown) while the indium composition to optimize lattice matching is gradually increased. However, the embodiments are not limited thereto. For example, the indium composition of the stress relief layer SRL may gradually increase from the lower portion to the upper portion, and decrease again at the uppermost layer. For example, in order to optimize lattice matching, the stress relief layer SRL may be grown by gradually increasing the indium composition, and in case that the growth of the stress relief layer SRL is about to be completed, the indium composition may be appropriately adjusted to match the target lattice size.

The doping concentration of the stress relief layer SRL may be uniform or non-uniform. For example, the doping concentration of the stress relief layer SRL may be uniform overall or may gradually change from the lower portion to the upper portion along the third direction DR3.

In one embodiment, the doping concentration of the stress relief layer SRL may gradually decrease from the lower portion to the upper portion. Accordingly, diffusion of the dopant of the stress relief layer SRL into the light emitting layer EML may be prevented or reduced.

Referring to FIGS. 9 and 10 in addition to FIGS. 1 to 8, the stress relief layer SRL may be formed as multiple layers including at least one pair of an indium-containing layer SRL1 and an intermediate layer SRL2 sequentially or alternately disposed on the superlattice layer SLT and/or the spacer layer SPL (or the first semiconductor layer SEM1) along the third direction DR3. As an example, the stress relief layer SRL may have a multilayer structure including indium-containing layers SRL1 and intermediate layers SRL2 alternately disposed on the spacer layer SPL in the third direction DR3.

The indium-containing layer SRL1 may include indium. For example, the indium-containing layer SRL1 may include a nitride-based semiconductor material including indium. As an example, the indium-containing layer SRL1 may include InGaN or InAlGaN and may be doped with a first conductivity type.

In one embodiment, the indium composition of the indium-containing layer SRL1 may be in a range of about 30% to about 100% of the indium composition of the quantum well layer QWL. In one embodiment, the doping concentration of the indium-containing layer SRL1 may be about 1016/cm³ or more and may be lower than the doping concentration of the first semiconductor layer SEM1. In one embodiment, the thickness of the indium-containing layer SRL1 may be about 2 nm or more and may be several micrometers (for example, about 3 μm) or less. In one embodiment, the indium-containing layer SRL1 disposed on the uppermost layer of the stress relief layer SRL may be directly in contact with the light emitting layer EML. In one embodiment, the indium-containing layer SRL1 disposed on the lowermost layer of the stress relief layer SRL may be in direct contact with the spacer layer SPL, or may be disposed close to the spacer layer SPL with one intermediate layer SRL2 therebetween.

The indium composition of the indium-containing layers SRL1 may be uniform or non-uniform. For example, as in the embodiment of FIG. 9, the indium composition of the indium-containing layers SRL1 may be substantially the same. By way of example, as in the embodiment of FIG. 10, the indium composition of the indium-containing layers SRL1 may gradually change from the indium-containing layer SRL1 at the lower portion adjacent to the first semiconductor layer SEM1, to the indium-containing layer SRL1 at the upper portion adjacent to the light emitting layer EML. For example, the indium composition of the indium-containing layers SRL1 may gradually increase or gradually increase and decrease, along the third direction D3.

In one embodiment, the indium-containing layer SRL1 may be doped. As an example, the indium-containing layer SRL1 may be doped with a first conductivity type. The doping concentration of the indium-containing layers SRL1 may be uniform or non-uniform. For example, the doping concentration of the indium-containing layers SRL1 may be substantially the same or may gradually change (for example, gradually decrease) along the third direction DR3.

The intermediate layers SRL2 may be disposed between the indium-containing layers SRL1. Each of the intermediate layers SRL2 may not include indium. For example, the intermediate layer SRL2 may include a nitride-based semiconductor material that does not include indium. As an example, the intermediate layer SRL2 may include GaN. The intermediate layers SRL2 may be doped or undoped.

By sequentially forming (for example, growing) the indium-containing layers SRL1 while the intermediate layers SRL2 are formed between the indium-containing layers SRL1, the indium-containing layers SRL1 may be formed more smoothly and/or appropriately. Accordingly, the high-quality and/or high-efficiency light emitting element LE with reduced defects may be manufactured.

In one embodiment, the doping concentration of the indium-containing layers SRL1 and/or the intermediate layers SRL2 may be uniform or non-uniform. For example, the doping concentration of the indium-containing layers SRL1 and/or the intermediate layers SRL2 may be uniform overall or may gradually change from the lower portion to the upper portion along the third direction DR3.

In one embodiment, the doping concentration of the indium-containing layers SRL1 and/or the intermediate layers SRL2 may gradually decrease from the lower portion to the upper portion. Accordingly, diffusion of the dopant of the indium-containing layers SRL1 and/or the intermediate layers SRL2 into the light emitting layer EML may be prevented or reduced.

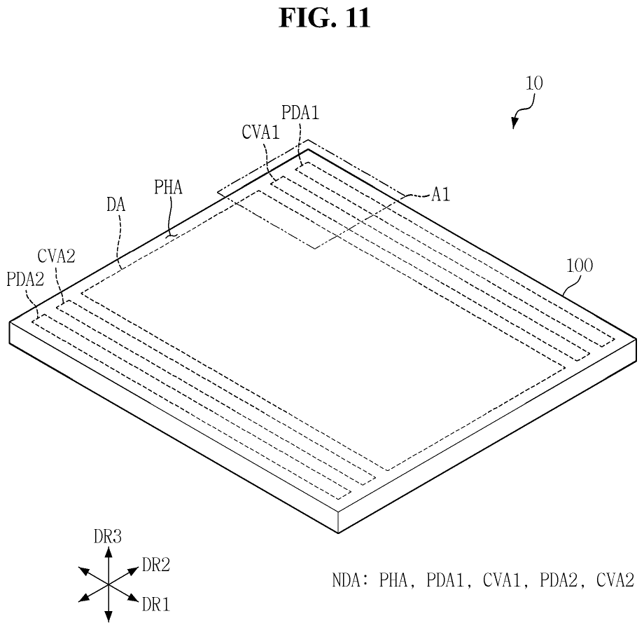

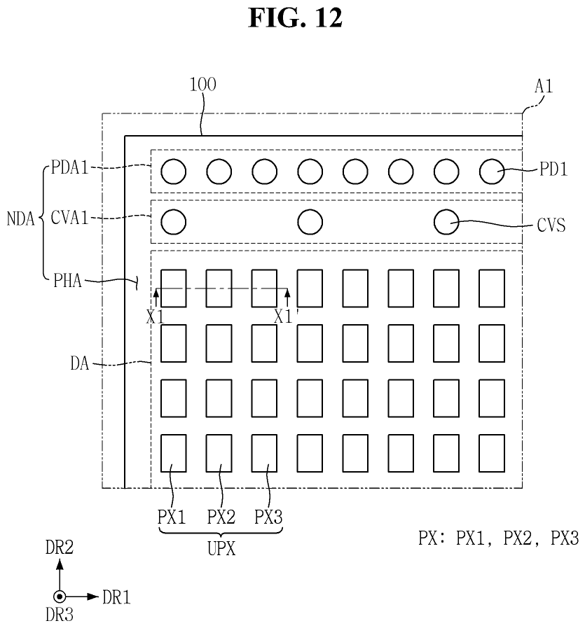

FIG. 11 is a schematic perspective view illustrating the display device 10 according to one embodiment. FIG. 12 is a schematic plan view showing an example of area μl of FIG. 11.

Referring to FIGS. 11 and 12, the display device 10 according to one embodiment may include a display panel 100 including a display area DA and a non-display area NDA.

The display panel 100 may have a quadrilateral planar shape having long sides in the first direction DR1 and short sides in the second direction DR2. In FIGS. 11 and 12, the first direction DR1 may refer to a horizontal direction (or vertical direction) of the display panel 100, and the second direction DR2 may refer to a vertical direction (or horizontal direction) of the display panel 100. The third direction DR3 may refer to a thickness direction or a height direction of the display panel 100. However, the planar shape of the display panel 100 is not limited thereto, and the display panel 100 may have a different shape. For example, the display panel 100 may have a polygonal shape other than a quadrilateral shape, a circular shape, an elliptical shape, or an irregular planar shape.

The display area DA may be an area where an image is displayed, and the non-display area NDA may be an area where an image is not displayed. In one embodiment, the planar shape of the display area DA may follow the planar shape of the display panel 100. FIG. 1 illustrates an embodiment in which the display area DA has a quadrilateral shape in plan view. The display area DA may be disposed in a central area of the display panel 100. The non-display area NDA may be disposed around the display area DA. For example, the non-display area NDA may surround the display area DA.

The display panel 100 may include pixels PX arranged or disposed in the display area DA. For example, the display panel 100 may include first pixels PX1 (for example, first color sub-pixels) that emit light of a first color, second pixels PX2 (for example, second color sub-pixels) that emit light of a second color, and third pixels PX3 (for example, third color sub-pixels) that emit light of a third color. In one embodiment, the first color may be red, the second color may be green, and the third color may be blue, but they are not limited thereto. At least one first pixel PX1, at least one second pixel PX2, and at least one third pixel PX3 adjacent to each other may constitute each unit pixel UPX capable of emitting light of various colors. As an example, the first pixel PX1, the second pixel PX2, and the third pixel PX3 sequentially disposed along the first direction DR1 in the Kth (K is a natural number) row of the display area DA may constitute one unit pixel UPX. The number, type, and/or arrangement structure of the pixels PX constituting the unit pixel UPX may be changed variously depending on the embodiments.

Each pixel PX may include at least one light emitting element LE. In one embodiment, the pixels PX may include the respective light emitting elements LE that emit light of different colors. For example, the first pixels PX1, the second pixels PX2, and the third pixels PX3 may include the light emitting elements LE emitting light of the first color, light of the second color, and light of the third color, respectively. However, the embodiments are not limited thereto. For example, the first pixels PX1, the second pixels PX2, and the third pixels PX3 may include light emitting elements LE that emit light of the same color, and light conversion patterns (for example, wavelength conversion patterns including quantum dots) and/or color filters to convert or control the color of light emitted from the light emitting elements LE provided in each of the pixels PX may be disposed in the emission areas of the first pixels PX1, the second pixels PX2, and/or the third pixels PX3.

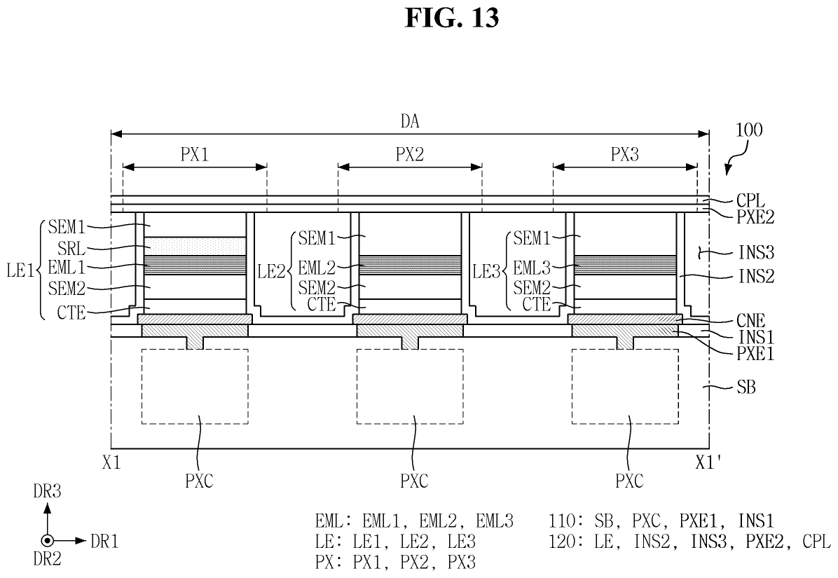

In one embodiment, at least one pixel PX may include the light emitting element LE according to at least one of the previously described embodiments. For example, each of the first pixels PX1 may include the light emitting element LE (for example, a first light emitting element LE1 of FIG. 13) including the stress relief layer SRL as in at least one of the embodiments described in FIGS. 1 to 10.

The pixels PX may include light emitting elements LE of substantially the same size, or may include light emitting elements LE of different sizes. For example, the first pixels PX1, the second pixels PX2, and the third pixels PX3 may include the light emitting elements LE having substantially the same size, or may include the light emitting elements LE having different sizes.

The pixels PX may include light emitting elements LE having substantially the same structure, or may include the light emitting elements LE having different structures. For example, each of the first pixels PX1, second pixels PX2, and third pixels PX3 may include the light emitting element LE including the stress relief layer SRL. By way of example, some of the first pixels PX1, the second pixels PX2, and the third pixels PX3 (for example, the first pixels PX1) may include the respective light emitting elements LE including the stress relief layer SRL according to the embodiments described above, and some others of the first pixels PX1, the second pixels PX2, and the third pixels PX3 (for example, the second pixels PX2 and/or the third pixels PX3) may include the respective light emitting elements LE that do not include the stress relief layer SRL.

In one embodiment, the pixels PX may be arranged or disposed in the display area DA in a matrix form, a stripe form, or any other form. The sizes of the pixels PX (or the emission areas of the pixels PX) may be substantially the same or different from each other. For example, the first pixels PX1, the second pixels PX2, and the third pixels PX3 may have substantially the same size (for example, the same area) or may have different sizes. The arrangement type, location, or size of the pixels PX may be variously changed depending on embodiments.

In one embodiment, the pixels PX may have a quadrilateral planar shape such as a rectangular shape or a rhombic shape, but the embodiments are not limited thereto. For example, the pixels PX may have a quadrilateral shape or other polygonal shape (for example, a rhombic shape or a hexagonal shape), a circular shape, an elliptical shape, or other planar shapes.

The non-display area NDA may include a first common voltage supply area CVA1, a second common voltage supply area CVA2, a first pad area PDA1, a second pad area PDA2, and a peripheral area PHA.

The first common voltage supply area CVA1 may be disposed between the first pad area PDA1 and the display area DA. The second common voltage supply area CVA2 may be disposed between the second pad area PDA2 and the display area DA. Each of the first common voltage supply area CVA1 and the second common voltage supply area CVA2 may include a common electrode connection portion CVS electrically connected to the second pixel electrode (for example, common electrode) of each of the pixels PX. The second pixel voltage (for example, a low-potential pixel voltage or a common voltage) may be supplied to the pixels PX through the common electrode connection portions CVS.

The common electrode connection portions CVS may be disposed in a common voltage supply area (for example, the first common voltage supply area CVA1 and/or the second common voltage supply area CVA2) of the non-display area NDA. The common electrode connection portions CVS may include a conductive material (for example, a metal material such as aluminum (Al)). FIGS. 11 and 12 illustrate the display device 10 in which the common electrode connection portions CVS are positioned in the non-display area NDA, but the embodiments are not limited thereto. For example, the common electrode connection portions CVS may be positioned in the display area DA.

The common electrode connection portions CVS of the first common voltage supply area CVA1 may be electrically connected to any one of the first pads PD1 of the first pad area PDA1. For example, the common electrode connection portions CVS of the first common voltage supply area CVA1 may receive a second pixel voltage (for example, a common voltage) from any one of the first pads PD1 of the first pad area PDA1.

The first pads PD1 may be disposed in the first pad area PDA1. The first pads PD1 may be connected to a circuit board (not illustrated) through a conductive connection member. For example, the first pads PD1 may be electrically connected to a circuit pad provided on the circuit board through a wire.

The common electrode connection portions CVS of the second common voltage supply area CVA2 may be electrically connected to any one of second pads of the second pad area PDA2. For example, the common electrode connection portions CVS of the second common voltage supply area CVA2 may receive the second pixel voltage from any one of the second pads of the second pad area PDA2. In one embodiment, the display panel 100 may not include the second common voltage supply area CVA2.

The first pad area PDA1 may be disposed on one side or a side (for example, an upper side) of the display panel 100. The first pad area PDA1 may include the first pads PD1 to be connected to an external circuit board.

The second pad area PDA2 may be disposed on one side or a side (for example, a lower side) of the display panel 100. The second pad area PDA2 may include the second pads to be connected to an external circuit board. In one embodiment, the display panel 100 may not include the second pad area PDA2.

The second pads may be disposed in the second pad area PDA2 of the non-display area NDA. The second pads may be connected to a circuit board (not illustrated) through a conductive connection member. For example, the second pads may be electrically connected to the circuit pads provided on the circuit board through wires.

The peripheral area PHA may be the remaining area except the first common voltage supply area CVA1, the second common voltage supply area CVA2, the first pad area PDA1, and the second pad area PDA2 in the non-display area NDA. The peripheral area PHA may surround not only the display area DA but also the first common voltage supply area CVA1, the second common voltage supply area CVA2, the first pad area PDA1, and the second pad area PDA2.

FIG. 13 is a schematic cross-sectional view illustrating the display panel 100 according to one embodiment. For example, FIG. 13 illustrates one embodiment of a cross section of the display panel 100 corresponding to line X1-X1′ of FIG. 12, and illustrates a schematic cross section of the first pixel PX1, the second pixel PX2, and the third pixel PX3 adjacent to each other in the first direction DR1.

FIG. 13 illustrates one embodiment in which the display device 10 is a light emitting diode on silicon (LEDoS) in which light emitting diodes are disposed as the light emitting elements LE, on a semiconductor circuit substrate 110 formed by a semiconductor process using a silicon wafer. However, a device including light emitting elements LE according to embodiments is not limited thereto. For example, the light emitting elements LE manufactured according to embodiments may be applied to display devices of different types and/or structures, or may be applied to devices of different types and/or structures, such as lighting devices.

Referring to FIGS. 11 to 13 in addition to FIGS. 1 to 10, the display panel 100 may include the semiconductor circuit substrate 110 and a light emitting element layer 120. In one embodiment, the display panel 100 may further include connection electrodes CNE that are disposed on the semiconductor circuit substrate 110 and connect pixel circuits PXC of the semiconductor circuit substrate 110 to the light emitting elements LE of the light emitting element layer 120.

In one embodiment, the display panel 100 may further include an additional configuration. As an example, the display panel 100 may further include at least one of a light conversion layer for converting the color and/or wavelength of light emitted from at least some of the light emitting elements LE, a color filter layer for performing control such that light of a given color is emitted from each of the emission areas, or an emission structure (for example, a lens, or the like) for improving the light emission efficiency of the pixels PX. In one embodiment, the light conversion layer, the color filter layer, and/or the emission structure may be disposed on the light emitting element layer 120.

The semiconductor circuit substrate 110 may include the display area DA in which the pixel circuits PXC of the pixels PX are formed. The semiconductor circuit substrate 110 may further include the non-display area NDA illustrated in FIGS. 11 and 12. For example, the semiconductor circuit substrate 110 may further include the common electrode connection portions CVS, the first pads PD1, and/or second pads positioned in the non-display area NDA.

The semiconductor circuit substrate 110 may include a base substrate SB and the pixel circuits PXC disposed or formed on the base substrate SB. The semiconductor circuit substrate 110 may further include first pixel electrodes PXE1 connected to each of the pixel circuits PXC and a first insulating layer INS1 disposed around the pixel electrodes PXE1.

The semiconductor circuit substrate 110 may further include lines. For example, the semiconductor circuit substrate 110 may further include lines (for example, power lines and signal lines) connected to the pixels PX.

In one embodiment, the semiconductor circuit substrate 110 may be formed through a semiconductor process using a silicon wafer. For example, the base substrate SB may be a silicon wafer. In one embodiment, the base substrate SB may be made of monocrystalline silicon.

The pixel circuits PXC may be disposed on the semiconductor circuit substrate 110 corresponding to each pixel area in which each of the pixels PX is disposed. In one embodiment, each of the pixel circuits PXC may include a complementary metal-oxide semiconductor (CMOS) circuit formed using a semiconductor process. In one embodiment, each of the pixel circuits PXC may include at least one transistor and at least one capacitor formed by the semiconductor process. FIG. 13 illustrates a schematic position of the pixel circuits PXC provided in the first pixel PX1, the second pixel PX2, and the third pixel PX3, as an example of elements provided on the semiconductor circuit substrate 110.

The first pixel electrodes PXE1 may be disposed on the pixel circuits PXC, respectively. The first pixel electrodes PXE1 may be connected to the pixel circuits PXC, respectively. For example, the pixel circuit PXC of each of the pixels PX may be electrically connected to the first pixel electrode PXE1 of the corresponding pixel PX. The first pixel electrodes PXE1 may receive a first pixel voltage or an anode voltage from the pixel circuits PXC, respectively.

In one embodiment, the first pixel electrodes PXE1 may be integral with the respective pixel circuits PXC. As an example, the first pixel electrodes PXE1 may be exposed electrodes that protrude from the top surfaces of the respective pixel circuits PXC.

The first pixel electrodes PXE1 may include at least one conductive material. For example, the first pixel electrodes PXE1 may include copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof. In one embodiment, the first pixel electrodes PXE1 may have a multilayer structure of double or more layers.

The first insulating layer INS1 may surround the first pixel electrodes PXE1. As an example, the first insulating layer INS1 may be disposed on the base substrate SB to surround the side surfaces of the first pixel electrodes PXE1.

The first insulating layer INS1 may include openings corresponding to the first pixel electrodes PXE1. As an example, the first insulating layer INS1 may be open to expose the upper surfaces of the first pixel electrodes PXE1.

The first insulating layer INS1 may include at least one insulating material and may have a single-layer or multilayer structure. In one embodiment, the first insulating layer INS1 may include at least one inorganic insulating layer including an inorganic insulating material (for example, silicon oxide (SiOₓ), silicon nitride (SiNₓ), aluminum oxide (AlₓO_{y}), titanium oxide (TiₓO_{y}), hafnium oxide (HfOₓ), or other inorganic insulating materials).

The connection electrodes CNE may be disposed on the first pixel electrodes PXE1. In one embodiment, the connection electrodes CNE may be disposed on the semiconductor circuit substrate 110 to be directly disposed or formed on the respective first pixel electrodes PXE1, but are not limited thereto. The connection electrodes CNE may be electrically connected to the respective first pixel electrodes PXE1.

The connection electrodes CNE may serve as a bonding metal for adhering the first pixel electrodes PXE1 to the light emitting elements LE. For example, the respective light emitting element LE may be bonded to the connection electrodes CNE. The light emitting elements LE may be electrically connected to the respective first pixel electrodes PXE1 through the connection electrodes CNE.

The connection electrodes CNE may include conductive metal. For example, the connection electrodes CNE may include at least one of gold (Au), copper (Cu), tin (Sn), titanium (Ti), aluminum (Al), or silver (Ag). The connection electrodes CNE may reduce contact resistance between the light emitting elements LE and the first pixel electrodes PXE1.

In one embodiment, the connection electrodes CNE may have a larger area than the light emitting elements LE. For example, the connection electrodes CNE may protrude outward from the light emitting elements LE when viewed in plan view.

In one embodiment, the display panel 110 may not include the connection electrodes CNE. As an example, the respective light emitting elements LE may be directly disposed or connected to the first pixel electrodes PXE1.

The light emitting element layer 120 may include light emitting elements LE of the pixels PX and a second pixel electrode PXE2. In one embodiment, the light emitting element layer 120 may further include at least one of a second insulating layer INS2, a third insulating layer INS3, or a capping layer CPL.

The light emitting elements LE may be disposed on the respective connection electrodes CNE. For example, the light emitting element LE of each of the pixels PX may be bonded onto the connection electrode CNE of the corresponding pixel PX, and may be electrically connected to the first pixel electrode PXE1 and the pixel circuit PXC of the corresponding pixel PX through the connection electrode CNE. As an example, the first light emitting element LE1 provided in the first pixel PX1 may be disposed on the connection electrode CNE of the first pixel PX1, and may be electrically connected to the first pixel electrode PXE1 and the pixel circuit PXC of the first pixel PX1 through the connection electrode CNE. The second light emitting element LE2 provided in the second pixel PX2 may be disposed on the connection electrode CNE of the second pixel PX2, and may be electrically connected to the first pixel electrode PXE1 and the pixel circuit PXC of the second pixel PX2 through the connection electrode CNE. The third light emitting element LE3 provided in the third pixel PX3 may be disposed on the connection electrode CNE of the third pixel PX3, and may be electrically connected to the first pixel electrode PXE1 and the pixel circuit PXC of the third pixel PX3 through the connection electrode CNE.

Each of the light emitting elements LE may include the first semiconductor layer SEM1 and the second semiconductor layer SEM2 respectively doped with a first conductivity type and a second conductivity type, and the light emitting layer EML disposed between the first semiconductor layer SEM1 and the second semiconductor layer SEM2. In one embodiment, the light emitting layer EML may include the quantum well layer QWL including a nitride-based semiconductor material including indium. The quantum well layer QWL may include indium in a composition corresponding to the emission wavelength of each of the light emitting elements LE.

In one embodiment, each of the light emitting elements LE may further include the contact electrode CTE. The contact electrode CTE may be disposed on the connection electrode CNE of the corresponding pixel PX to be connected to the connection electrode CNE.

In one embodiment, the first light emitting element LE1, the second light emitting element LE2, and the third light emitting element LE3 may emit light of different colors. For example, the first light emitting element LE1, the second light emitting element LE2, and the third light emitting element LE3 may emit light of the first color (for example, red light), light of the second color (for example, green light), and light of the third color (for example, blue light), respectively. In this case, the light emitting layer EML (hereinafter referred to as a “first light emitting layer EML1”) of the first light emitting element LE1, the light emitting layer EML (hereinafter referred to as a “second light emitting layer EML2”) of the second light emitting element LE2, and the light emitting layer EML (hereinafter referred to as a “third light emitting layer EML3”) of the third light emitting element LE3 may emit light in different wavelength bands. The first light emitting layer EML1, the second light emitting layer EML2, and the third light emitting layer EML3 may include indium in different compositions. For example, the quantum well layer QWL of the first light emitting layer EML1, which emits light of a longer wavelength, may include indium in a higher composition than the quantum well layer QWL of each of the second light emitting layer EML2 and the third light emitting layer EML3.

In one embodiment, at least one light emitting element LE may further include the stress relief layer SRL. For example, the light emitting element LE that emits light of a long wavelength that is greater than or equal to a given wavelength band may further include the stress relief layer SRL including indium in a range of about 30% to about 100% of the indium composition of the quantum well layer QWL included in the light emitting layer EML.

In one embodiment, the first light emitting element LE1 emits light (for example, red light) of a longer wavelength than the second light emitting element LE2 and the third light emitting element LE3, and may include the stress relief layer SRL disposed between the first semiconductor layer SEM1 and the first light emitting layer EML1. The stress relief layer SRL of the first light emitting element LE1 may include at least one indium-containing layer including a nitride-based semiconductor material including indium in a composition in a range of about 30% to about 100% of the indium composition of the quantum well layer QWL included in the first light emitting layer EML. The stress relief layer SRL of the first light emitting element LE1 may be doped. As an example, the stress relief layer SRL of the first light emitting element LE1 may be doped at a concentration of about 1016/cm 3 or more. Accordingly, although a high current corresponding to a high-gray scale data signal flows through the first light emitting element LE1, light may not be generated in the stress relief layer SRL.

Each of the second light emitting element LE2 and the third light emitting element LE3 may include or may not include the stress relief layer SRL disposed between the light emitting layer EML (for example, the second light emitting layer EML2 or the third light emitting layer EML3) and the first semiconductor layer SEM1. For example, as in the embodiment of FIG. 13, the second light emitting element LE2 and the third light emitting element LE3 may not include the stress relief layer SRL. In an embodiment, each of the first light emitting element LE1 and the second light emitting element LE2 may include the stress relief layer SRL, and the third light emitting element LE3 may not include the stress relief layer SRL. In an embodiment, each of the first light emitting element LE1, the second light emitting element LE2, and the third light emitting element LE3 may include the stress relief layer SRL. The stress relief layer SRL of the light emitting elements LE may include an indium-containing layer including indium in a composition corresponding to the composition ratio of indium included in each of the light emitting layers EML.

In case that at least one of the second light emitting element LE2 or the third light emitting element LE3 does not include the stress relief layer SRL, the light emitting elements LE provided in the pixels PX may have different structures according to the emission wavelength. As an example, the first light emitting element LE1 may include the stress relief layer SRL, and at least one of the second light emitting element LE2 or the third light emitting element LE3 may not include the stress relief layer SRL.

In one embodiment, at least one light emitting element LE may further include the superlattice layer SLT. For example, at least one of the first light emitting element LE1, the second light emitting element LE2, or the third light emitting element LE3 may further include the superlattice layer SLT according to the embodiments described above. In one embodiment, the light emitting element LE including the superlattice layer SLT may further include the spacer layer SPL disposed between the superlattice layer SLT and the stress relief layer SRL (or the first semiconductor layer SEM1), or may not include the spacer layer SPL.

The second insulating layer INS2 may be disposed around the light emitting elements LE to surround at least a part of the light emitting elements LE. As an example, the second insulating layer INS2 may be disposed on the semiconductor circuit substrate 110 and may surround the side surfaces of the light emitting elements LE.

The second insulating layer INS2 may include openings exposing a part of the light emitting elements LE. For example, the second insulating layer INS2 may be open to expose the upper surfaces (for example, one of the surfaces of the first semiconductor layers SEM1) of the light emitting elements LE.

The second insulating layer INS2 may include at least one insulating material and may have a single-layer or multilayer structure. In one embodiment, the second insulating layer INS2 may include at least one inorganic insulating layer including an inorganic insulating material. The second insulating layer INS2 may be omitted.

The third insulating layer INS3 may be disposed around the light emitting elements LE and/or the second insulating layer INS2. For example, the third insulating layer INS3 may be filled between the light emitting elements LE surrounded by the second insulating layer INS2. In one embodiment, the third insulating layer INS3 may be formed to have substantially the same height or a similar height to the light emitting elements LE, and thus may reduce the stepped portion caused by the light emitting elements LE.

In one embodiment, the third insulating layer INS3 may include an organic insulating material. For example, the third insulating layer INS3 may be a single-layer or multilayer organic insulating layer containing acrylic resin, epoxy resin, phenolic resin, polyamide resin, and polyimide resin, or other organic insulating materials. In another embodiment, the third insulating layer INS3 may include at least one inorganic insulating layer including an inorganic insulating material such as silicon oxide (SiOₓ) or other inorganic insulating materials, and the third insulating layer INS3 may optionally be planarized.

The second pixel electrode PXE2 may be disposed on the light emitting elements LE and may be connected to the light emitting elements LE. As an example, the second pixel electrode PXE2 may be disposed on the first semiconductor layers SEM1 of the light emitting elements LE.

In one embodiment, the second pixel electrode PXE2 may be entirely disposed in the display area DA. As an example, the second pixel electrode PXE2 may be disposed on the light emitting elements LE and the third insulating layer INS3, and may be formed as a common electrode shared by the pixels PX. The second pixel electrode PXE2 may be connected to at least one common electrode connection portion CVS or a power line (for example, a second pixel power line) connected thereto, and may be supplied with a second pixel voltage (for example, a common voltage) or a cathode voltage. In an embodiment, the pixels PX may include the respective second pixel electrodes PXE2 individually separated, and the second pixel electrodes PXE2 may be commonly connected to the common electrode connection portion CVS.

The capping layer CPL may be disposed on the second pixel electrode PXE2. For example, the capping layer CPL may be entirely disposed in the display area DA to cover the second pixel electrode PXE2. In one embodiment, the capping layer CPL may include at least one inorganic insulating layer including an inorganic insulating material.

In one embodiment, the display panel 100 may further include an additional configuration. For example, the display panel 100 may further include at least one of a reflective layer and a light blocking layer disposed around the light emitting elements LE, or an overcoat layer disposed on the capping layer CPL.

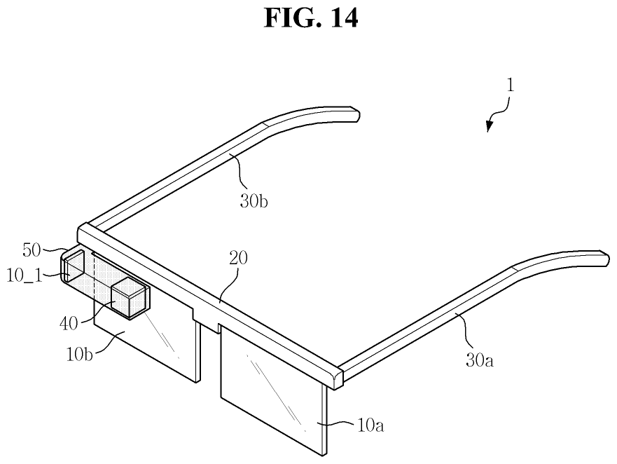

FIG. 14 is a diagram illustrating a virtual reality device 1 including a display device 10_1 according to one embodiment.

Referring to FIG. 14, the virtual reality device 1 according to one embodiment may be a glass-type device. The virtual reality device 1 according to one embodiment may include a display device 10_1, a left lens 10a, a right lens 10b, a support frame 20, temples 30a and 30b, a reflection member 40, and a display device housing 50.

Although FIG. 14 illustrates the virtual reality device 1 including the temples 30a and 30b, the embodiments are not limited thereto. For example, the virtual reality device 1 may be applied to a head mounted display including a head mounted band that may be worn on a head, instead of the temples 30a and 30b. The virtual reality device 1 according to embodiments may be applied in various forms to other electronic devices.

The display device housing 50 may include the display device 10_1 and the reflection member 40. The image displayed on the display device 10_1 may be reflected by the reflection member 40 and provided to a user's right eye through the right lens 10b. Accordingly, the user can view the virtual reality image displayed on the display device 10_1 through the right eye.

Although FIG. 14 illustrates that the display device housing 50 is disposed at the right end of the support frame 20, the embodiments are not limited thereto. For example, the display device housing 50 may be disposed at the left end of the support frame 20, and in this case, the image displayed on the display device 10_1 may be reflected by the reflection member 40 and provided to a user's left eye through the left lens 10a. Accordingly, the user can view the virtual reality image displayed on the display device 10_1 through the left eye. By way of example, the display device housing 50 may be disposed at both the left end and the right end of the support frame 20. In that case, the user can view the virtual reality image displayed on the display device 10_1 through both the left eye and the right eye.

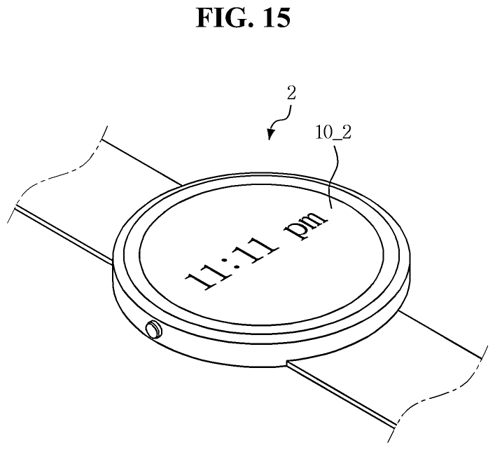

FIG. 15 is a diagram illustrating a smart device including a display device 10_2 according to one embodiment.

Referring to FIG. 15, the display device 10_2 according to one embodiment may be applied to a smart watch 2 that is one of the smart devices. The planar shape of a clock display unit of the smart watch 2 may follow the planar shape of the display device 10_2. For example, in case that the display device 10_2 according to one embodiment has a planar shape such as a circular shape or an elliptical shape, the clock display unit of the smart watch 2 may have a planar shape such as a circular shape or an elliptical shape. By way of example, in case that the display device 10_2 according to one embodiment has a quadrilateral planar shape, the clock display unit of the smart watch 2 may have a quadrilateral planar shape. However, the embodiments are not limited thereto, and the clock display unit of the smart watch 2 may not follow the planar shape of the display device 10_2.

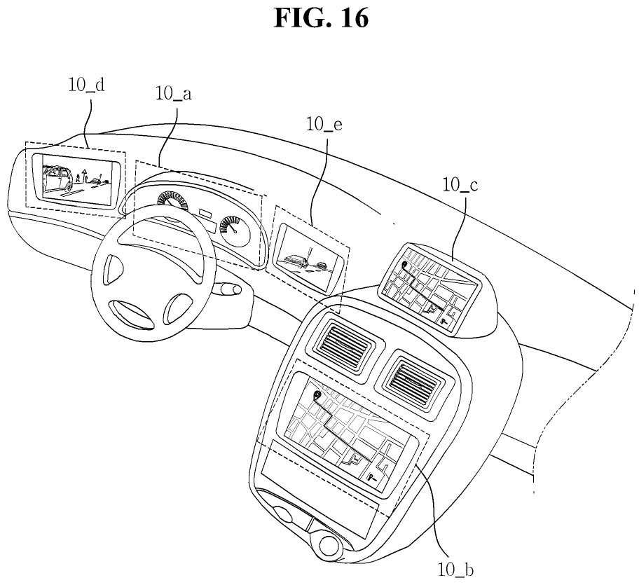

FIG. 16 illustrates an automobile dashboard and center fascia including display devices 10_a, 10_b, 10_c, 10_d, and 10_e according to one embodiment. FIG. 15 illustrates a vehicle to which display devices 10_a, 10_b, 10_c, 10_d, and 10_e according to one embodiment are applied.

Referring to FIG. 16, the display devices 10_a, 10_b, and 10_c according to one embodiment may be applied to the dashboard of the automobile, the center fascia of the automobile, or the center information display (CID) of the dashboard of the automobile. By way of example, the display devices 10_d, and 10_e according to one embodiment may be applied to a room mirror display instead of side mirrors of the automobile.

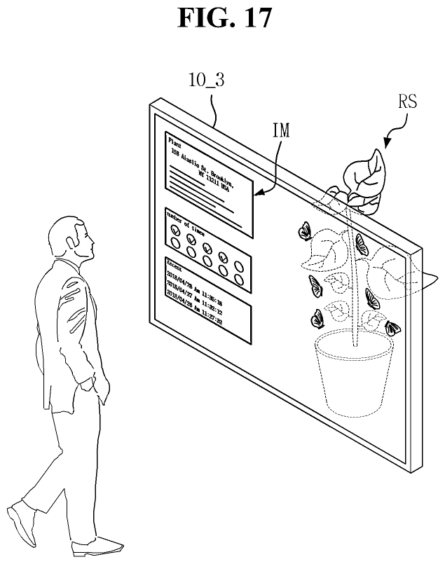

FIG. 17 is a diagram illustrating a transparent display device including a display device 10_3 according to one embodiment.

Referring to FIG. 17, the display device 10_3 according to one embodiment may be applied to the transparent display device. The transparent display device may display an image IM, and also may transmit light. Accordingly, a user located in front of the transparent display device can view an object RS or a background located behind the transparent display device as well as the image IM displayed on the display device 10_3. In case that the display device 10_3 is applied to a transparent display device, the display panel 100 may include a light transmission portion capable of transmitting light or may be formed on a substrate member made of a material capable of transmitting light.

In concluding the detailed description, those skilled in the art will appreciate that many variations and modifications can be made to the embodiments without substantially departing from the principles of the disclosure. Therefore, the disclosed embodiments are used in a generic and descriptive sense only and not for purposes of limitation.

What is claimed is:

1. A light emitting element comprising:
a first semiconductor layer doped with a first conductivity type;
a stress relief layer disposed on the first semiconductor layer, the stress relief layer comprising an indium-containing layer containing a nitride-based semiconductor material containing indium, and doped with the first conductivity type;
a light emitting layer disposed on the stress relief layer, the light emitting layer comprising a quantum well layer containing a nitride-based semiconductor material containing indium in a composition greater than or equal to an indium composition of the indium-containing layer; and
a second semiconductor layer disposed on the light emitting layer and doped with a second conductivity type,
wherein the indium composition of the indium-containing layer is in a range of about 30% to about 100% of an indium composition of the quantum well layer.

2. The light emitting element of claim 1, wherein a doping concentration of the indium-containing layer is about 1016/cm³ or more.

3. The light emitting element of claim 1, wherein a doping concentration of the indium-containing layer is lower than a doping concentration of the first semiconductor layer.

4. The light emitting element of claim 1, wherein a thickness of the indium-containing layer is about 2 nm or more.

5. The light emitting element of claim 1, further comprising:
a superlattice layer disposed between the first semiconductor layer and the stress relief layer,
wherein the superlattice layer is formed as multiple layers in which a first layer containing a nitride-based semiconductor material containing indium and a second layer containing a nitride-based semiconductor material that does not contain indium are alternately disposed.

6. The light emitting element of claim 5, wherein an indium composition of the first layer of the superlattice layer is less than about 30% of the indium composition of the quantum well layer.

7. The light emitting element of claim 5, wherein the superlattice layer is doped at a doping concentration lower than or equal to a doping concentration of the first semiconductor layer.

8. The light emitting element of claim 5, further comprising:
a spacer layer disposed between the superlattice layer and the stress relief layer, the spacer layer containing a nitride-based semiconductor material that does not contain indium,
wherein a thickness of the spacer layer is about 20 nm or more.

9. The light emitting element of claim 1, wherein
the quantum well layer contains InGaN, and
the indium-containing layer contains InGaN or InAlGaN.

10. The light emitting element of claim 1, wherein the indium-containing layer directly contacts the light emitting layer.

11. The light emitting element of claim 1, wherein
the stress relief layer is a single layer formed of the indium-containing layer, and
an indium composition of the stress relief layer gradually changes from a lower portion adjacent to the first semiconductor layer to an upper portion adjacent to the light emitting layer.

12. The light emitting element of claim 1, wherein the stress relief layer is formed as multiple layers in which a plurality of indium-containing layers comprising the indium-containing layer and a plurality of intermediate layers containing a nitride-based semiconductor material that does not contain indium are alternately disposed.

13. The light emitting element of claim 12, wherein an indium composition of the plurality of indium-containing layers gradually changes from the indium-containing layer at a lower portion adjacent to the first semiconductor layer to the indium-containing layer at an upper portion adjacent to the light emitting layer.

14. The light emitting element of claim 1, wherein a doping concentration of the stress relief layer gradually changes from a lower portion adjacent to the first semiconductor layer to an upper portion adjacent to the light emitting layer.

15. The light emitting element of claim 14, wherein the doping concentration of the stress relief layer gradually decreases from a lower portion adjacent to the first semiconductor layer to an upper portion adjacent to the light emitting layer.

16. The light emitting element of claim 1, wherein an indium fluctuation in the light emitting layer is at least about 10% higher than an indium fluctuation in the stress relief layer.

17. The light emitting element of claim 1, wherein
the indium composition of the quantum well layer is about 25% or more, and
an emission wavelength of the light emitting layer is in a range of about 500 nm to about 750 nm.

18. A display device comprising:
a pixel comprising a first pixel electrode, a second pixel electrode, and a light emitting element electrically connected between the first pixel electrode and the second pixel electrode, wherein
the light emitting element comprises:
a first semiconductor layer doped with a first conductivity type;
a stress relief layer disposed on the first semiconductor layer, the stress relief layer comprising an indium-containing layer containing a nitride-based semiconductor material containing indium, and doped with the first conductivity type;
a light emitting layer disposed on the stress relief layer, the light emitting layer comprising a quantum well layer containing a nitride-based semiconductor material containing indium; and
a second semiconductor layer disposed on the light emitting layer and doped with a second conductivity type, and
an indium composition of the indium-containing layer is in a range of about 30% to about 100% of an indium composition of the quantum well layer.

19. The display device of claim 18, wherein a doping concentration of the indium-containing layer is about 1016/cm³ or more.

20. The display device of claim 18, wherein
the light emitting element further comprises a superlattice layer disposed between the first semiconductor layer and the stress relief layer, and
the superlattice layer contains a nitride-based semiconductor material containing indium in a composition less than about 30% of the indium composition of the quantum well layer.
